(19) United States
(12) Patent Application Publication
(10) Pub. No.: US 2014/0041721 A1
(43) Pub. Date: Feb. 13, 2014

(54) SOLAR CELL AND MANUFACTURING METHOD THEREOF

(71) Applicant: SAMSUNG SDI CO., LTD., Yongin-si (KR)

(72) Inventor: Hee-Yong Lee, Yongin-si (KR)

(73) Assignee: SAMSUNG SDI CO., LTD., Yongin-si (KR)

(21) Appl. No.: 13/844,074

(22) Filed: Mar. 15, 2013

Related U.S. Application Data
(60) Provisional application No. 61/681,303, filed on Aug. 9, 2012.

(51) Int. Cl. H01L 31/0224; H01L 31/18

(52) U.S. Cl. CPC H01L 31/022425; H01L 31/1884
USPC 136/256; 438/98

(57) ABSTRACT

A solar cell includes a substrate, a rear electrode layer on the substrate, the rear electrode layer including a plurality of metal columnar grain layers, a light absorbing layer on the rear electrode layer, and a transparent electrode layer on the light absorbing layer.

### CROSS-REFERENCE TO RELATED APPLICATION

This application claims priority to and the benefit of U.S. Provisional Application No. 61/681,303, filed on Aug. 9, 2012 in the U.S. Patent and Trademark Office, the entire content of which is incorporated herein by reference.

### BACKGROUND

1. Field

The described technology relates generally to a solar cell and a manufacturing method thereof.

2. Description of the Related Art

A solar cell is a photoelectric conversion device that converts light energy, such as solar light energy, into electrical energy. The solar cell includes a rear-surface electrode layer formed on a substrate, a light absorbing layer located thereon, and a transparent electrode layer.

A solar cell may be, for example, a silicon solar cell using silicon as a light absorption layer (or a photoelectric conversion layer), a compound semiconductor solar cell using compounds such as CIS (Cu, In, Se) or CIGS (Cu, In, Ga, Se), or the like. Among them, in a compound semiconductor solar cell, an alkali metal (e.g., sodium) may be included in the light absorbing layer to increase efficiency of the light absorbing layer, and studies relating thereto have been undertaken. For example, a compound including an alkali metal may be directly added, or an alkali metal included in the substrate may be spread to the light absorbing layer.

Methods for spreading the alkali metal in the substrate to the light absorbing layer through the rear electrode layer have been studied, as such methods may cause problems, such as adherence of the rear electrode layer to the substrate, complexity of the manufacturing process, and control of the concentration of the alkali metal.

The above information disclosed in this Background section is only for enhancement of understanding of the background of the described technology, and therefore it may contain information that does not form the prior art that is already known in this country to a person of ordinary skill in the art.

### SUMMARY

Embodiments of the present invention provide a solar cell for controlling an alkali metal spread through a rear electrode layer for providing excellent adherence to a substrate through a relatively simple process, and a manufacturing method thereof.

According to an embodiment of the present invention, a method for manufacturing a solar cell includes placing oxygen atoms in the rear electrode layer through a relatively simple and easy process, and allows the alkali metal to be efficiently spread into the light absorbing layer by using the oxygen atoms. Also, according to embodiments of the present invention, a solar cell with excellent adherence between the substrate and the rear electrode layer may be realized.

According to one embodiment of the present invention, there is provided a solar cell including a substrate, a rear electrode layer on the substrate, the rear electrode layer including a plurality of metal columnar grain layers, a light absorbing layer on the rear electrode layer, and a transparent electrode layer on the light absorbing layer.

Each of the metal columnar grain layers may include molybdenum.

A thickness of each of the metal columnar grain layers may be between about 20 nm and about 500 nm.

The thickness of each of the metal columnar grain layers may be between about 50 nm and about 100 nm.

The solar cell may further include an interface between an adjacent pair of the metal columnar grain layers, the interface including oxygen atoms.

An amount of the oxygen atoms may be between about 1 atomic % and about 70 atomic % of a total amount of atoms of the rear electrode layer.

The amount of the oxygen atoms may be between about 1 atomic % and about 20 atomic % of the total amount of atoms of the rear electrode layer.

The rear electrode layer may include no more than 9 metal columnar grain layers.

The light absorbing layer may include at least one of Cu, In, Ga, or Se.

According to another embodiment of the present invention, there is provided a method of forming a solar cell, the method including placing a substrate in a deposition chamber, forming a rear electrode layer including a plurality of metal columnar grain layers, forming a light absorbing layer on the rear electrode layer, and forming a transparent electrode layer on the light absorbing layer.

Forming the rear electrode layer may include forming one of the metal columnar grain layers by depositing molybdenum on the substrate or on a previous one of the metal columnar grain layers, and forming a next one of the metal columnar grain layers by depositing molybdenum on the one of the metal columnar grain layers following a break time after forming the one of the metal columnar grain layers.

The break time may be between about 1 second and about 1 hour.

Oxygen atoms may be placed in the rear electrode layer during the break time.

An amount of the oxygen atoms placed in the rear electrode layer may correspond to at least one of a length of the break time or a number of break times.

According to another embodiment of the present invention, there is provided a method of forming a solar cell, the method including placing a substrate in a deposition chamber, forming a rear electrode layer by depositing molybdenum on the substrate to form a first metal columnar grain layer, and depositing molybdenum on the first metal columnar grain layer following a break time after forming the first metal columnar grain layer to form a second metal columnar grain layer on the first metal columnar grain layer.

Oxygen atoms may be placed in the rear electrode layer during the break time.

An amount of oxygen atoms may correspond to at least one of a length of the break time or a number of break times.

The break time may be between about 1 second and about 1 hour.

The molybdenum may be deposited under a pressure of about 0.05 Pa to about 5 Pa.

The molybdenum may be deposited by sputtering.

### BRIEF DESCRIPTION OF THE DRAWINGS

FIG. 1 shows a cross-sectional view of a solar cell according to an exemplary embodiment of the present invention.

FIG. 2 shows an enlarged view of the area II of the solar cell of the embodiment shown in FIG. 1.

FIGS. 3A to 3C show a method for manufacturing a rear electrode layer according to an exemplary embodiment of the present invention.

FIG. 4 shows a graph showing an atom ratio with respect to a thickness of the rear electrode layer as measured by X-ray photoelectron spectroscopy (XPS) according to an exemplary embodiment of the present invention.

FIGS. 5A and 5B respectively show photographs of a cross-section of a rear electrode layer, as captured by a scanning electron microscope (SEM) of an exemplary embodiment and of a comparative example.

FIG. 6 shows a graph of results of a peel strength test according to an exemplary embodiment and according to a comparative example.

### DETAILED DESCRIPTION

Embodiments of the present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

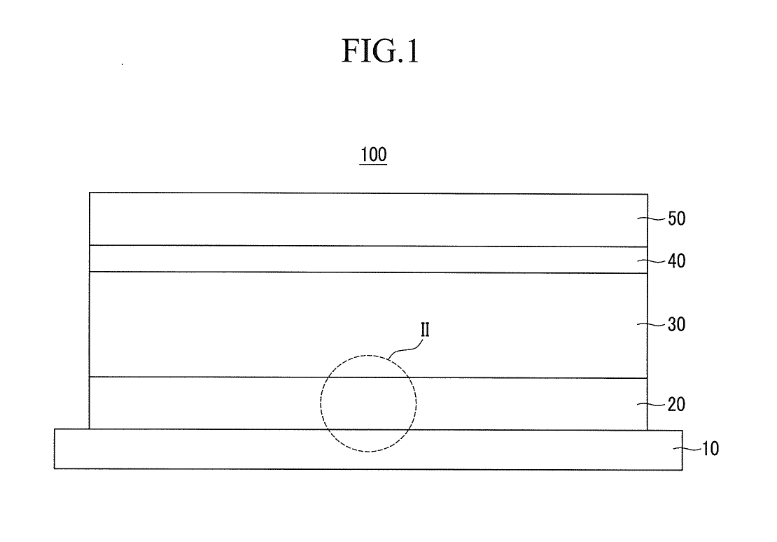

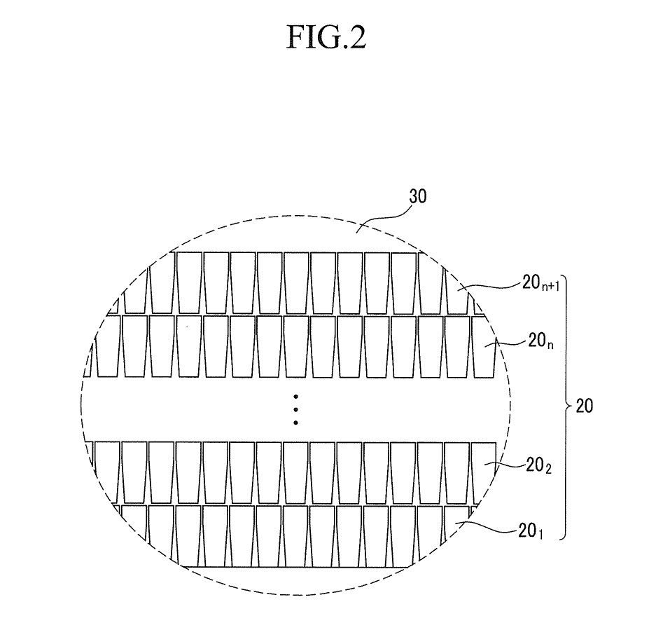

FIG. 1 shows a cross-sectional view of a solar cell according to an exemplary embodiment, and FIG. 2 shows an enlarged view of the area II of the solar cell of the embodiment shown in FIG. 1.

Referring to FIG. 1 and FIG. 2, the solar cell 100 includes a substrate 10, a rear electrode layer 20, a light absorbing layer 30, a buffer layer 40, and a transparent electrode layer 50.

The solar cell 100 may be, for example, a silicon solar cell using silicon for the light absorbing layer 30, or a compound semiconductor solar cell including CIS (Cu, In, Se) or CIGS (Cu, In, Ga, Se) for the light absorbing layer 30. The light absorbing layer 30 including the CIS or the CIGS will be exemplified hereinafter.

The substrate 10 is at an outermost side of the solar cell 100. That is, the substrate 10 is farthest from the side (e.g., surface) on which light is applied. The substrate 10 may be formed with various materials including, for example, plate-type glass, ceramic, stainless steel, metal, or film-type polymers.

The rear electrode layer 20 is located on the substrate 10, and is made of a metal with excellent optical reflective efficiency and with excellent adhesion to the substrate 10. For example, the rear electrode layer 20 may include molybdenum (Mo). Molybdenum (Mo) has high electrical conductivity, may form an ohmic contact with the light absorbing layer 30, and realizes great stability during a high temperature heat treatment for forming the light absorbing layer 30. An embodiment in which the rear electrode layer 20 is made of molybdenum (Mo) will be exemplified hereinafter.

As shown in FIG. 2, the rear electrode layer 20 has a multi-layered structure including a plurality of metal columnar grain layers 20₁-20ₙ₊₁. Here, n represents a number of break times during the metal deposition process during a process for forming the rear electrode layer 20 (to be described), and is an integer defined by 1≦n≦8. The metal columnar grain layers 20₁-20ₙ₊₁ are each made of molybdenum (Mo), and are vertically grown with different columnar grain forms so they are identified by existence of a grain boundary at an interface among the metal columnar grain layers 20₁-20ₙ₊₁.

The thickness of the individual metal columnar grain layers 20₁-20ₙ₊₁ may be, for example, 20 nm to 500 nm, and is 50 nm to 100 nm in the present embodiment. The total thickness of the rear metal layer 20 formed by the plurality of metal columnar grain layers 20₁-20ₙ₊₁ may be, for example, 100 nm to 1000 nm.

The interface of the metal columnar grain layers 20₁-20ₙ₊₁ includes oxygen atoms. The number (e.g., amount) of oxygen atoms may be, for example, 1 atomic % to 70 atomic % of the total number of atoms included in the rear metal layer 20, and is 1 atomic % to 20 atomic % in the present embodiment.

A light absorbing layer (or a photoelectric converting layer) 30 is located on the rear electrode layer 20, and generates electrons and holes by using the light energy transmitted through the transparent electrode layer 50 and the buffer layer 40. The light absorbing layer 30 may include, for example, a chalcopyrite compound semiconductor selected from among a group of CuInSe, CuInSe₂, CuInGaSe, and CuInGaSe₂.

The light absorbing layer 30 of the present embodiment may be manufactured by a first process of forming a precursor layer by sputtering copper (Cu) and indium (In), or copper (Cu), indium (In), and gallium (Ga), on the rear electrode layer 20, by a second process of thermally depositing selenium (Se) on the precursor layer, and by a third process of growing CIS (Cu, In, Se) or CIGS (Cu, In, Ga, Se) crystal by performing a fast heat treatment for more than one minute at a high temperature of greater than 550° C. In the present embodiment, during the fast heat treatment process, part of the selenium (Se) may be exchanged with sulfur (S) to prevent evaporation of selenium (Se), and an open voltage of the solar cell 100 may be increased by increasing an energy band gap of the light absorbing layer 30.

The buffer layer 40 may be placed on the light absorbing layer 30, and may relieve the energy band gap difference between the light absorbing layer 30 and the transparent electrode layer 50. Further, the buffer layer 40 lessens a lattice constant difference between the light absorbing layer 30 and the transparent electrode layer 50 to bond the layers 30 and 50. The buffer layer 40 includes one of cadmium sulfide (CdS), zinc sulfide (ZnS), and indium oxide (In₂O₃). The buffer layer 40 may be omitted in other embodiments of the present invention.

The transparent electrode layer 50 is located on the buffer layer 40, and may be formed with, for example, a metal oxide including boron-doped zinc oxide (BZO) with excellent optical transmittivity, zinc oxide (ZnO), indium oxide (In₂O₃), or indium tin oxide (ITO). The transparent electrode layer 50 has great electrical conductivity and optical transmittivity, and may have rough surface protrusions and depressions formed through an additional texturing process. Also, an antireflection layer (not shown) may be formed over the transparent electrode layer 50. The formation of the surface protrusions and depressions and the antireflection layer on the transparent electrode layer 50 reduces reflection of external light to increase transmission efficiency of sunlight toward the light absorbing layer 30.

The solar cell 100 includes the rear electrode layer 20 including a plurality of metal columnar grain layers 20₁-20ₙ₊₁, and an interface between the metal columnar grain layers 20₁-20ₙ₊₁ includes oxygen atoms so that the alkali metal (e.g., sodium) from the substrate 10 may be efficiently spread inside the light absorbing layer 30 during the heat treatment for forming the light absorbing layer 30. Further, the solar cell 100 has excellent adherence of the rear electrode layer 20 to the substrate 10.

A method of manufacturing the rear electrode layer 20 of the solar cell 100 according to an exemplary embodiment will now be described.

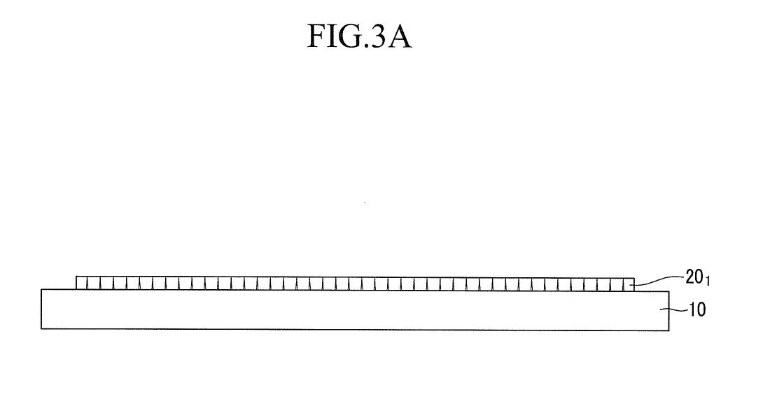

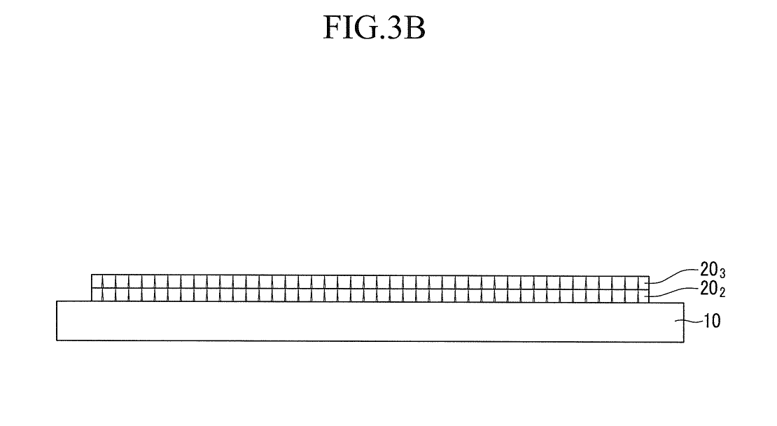

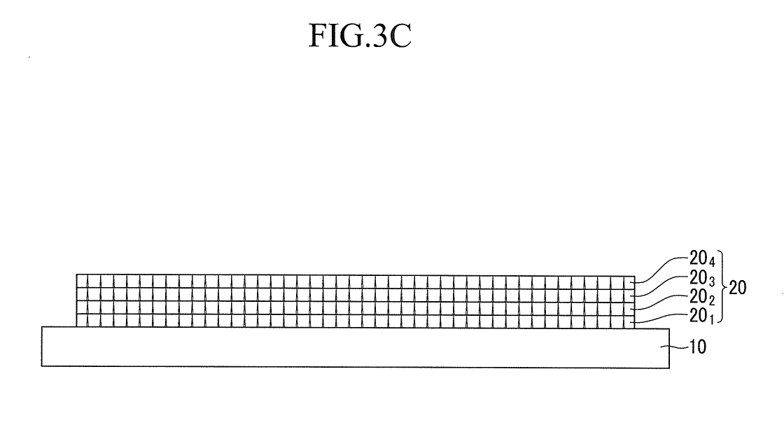

As shown in FIG. 3A, a first metal columnar grain layer 20₁ is formed on the substrate 10. The first metal columnar grain layer 20₁ may be formed by depositing molybdenum (Mo) on the substrate 10 through sputtering. The molybdenum may be deposited under a pressure of, for example, 0.05 Pa to 5 Pa until the first metal columnar grain layer 20₁ is sufficiently thick (e.g., reaches a predetermined thickness).

In the present embodiment, the thickness of the first metal columnar grain layer 20₁ is from 20 nm to 500 nm, and may be from 50 nm to 100 nm. A first break time is provided when the first metal columnar grain layer 20₁ is formed, wherein deposition of the molybdenum is paused (e.g., is stopped for a predetermined time). The duration of the first break time of the present embodiment may be from, for example, 1 second to 1 hour.

As shown in FIG. 3B, a second metal columnar grain layer 20₂ is formed on the first metal columnar grain layer 20₁, and is deposited under conditions similar to those for the first metal columnar grain layer 20₁. That is, the process of forming the first metal columnar grain layer 20₁ and the process of forming the second metal columnar grain layer 20₂ may be performed in the same chamber and under the same deposition conditions, and the delineation thereof is identified by the first break time. The thickness of the second metal columnar grain layer 20₂ may be from, for example, 20 nm to 500 nm, and may even be from 50 nm to 100 nm. A second break time is provided when the second metal columnar grain layers 20₂ is formed. That is, deposition of molybdenum is paused (e.g., stopped for a predetermined time). The second break time of the present embodiment may be from, for example, 1 second to 1 hour.

As shown in FIG. 3C, a third metal columnar grain layers 20₃ is additionally formed on the second metal columnar grain layers 20₂. The third metal columnar grain layers 20₃ is also formed in the same chamber and under the same deposition conditions, and the third metal columnar grain layers 20₃ is delineated by the break time between the metal columnar grain layers. The number of metal columnar grain layers 20₁-20ₙ₊₁ may be different in different embodiments of the present invention. For example, 2 to 9 layered metal columnar grain layers may be formed with 1 to 8 break times, respectively. A fourth metal columnar grain layer 20₄ is formed in the present embodiment. That is, after the second metal columnar grain layer 20₂ is formed, the second break time of a predetermined time is provided, and the third metal columnar grain layer 20₃ is then formed. After the third break time of one second to one hour, the fourth metal columnar grain layer 20₄ is formed.

Because the break time is provided between molybdenum deposition, oxygen atoms may be included in the interface between the metal columnar grain layers 20₁-20ₙ₊₁. The number of included oxygen atoms can be increased or reduced by adjusting the length of the break time, and the number of oxygen atoms included in the rear electrode layer 20 corresponds to the number of interfaces of the metal columnar grain layers 20₁-20ₙ₊₁. For example, the number of oxygen atoms may be 1 atomic % to 70 atomic % for the molybdenum atoms included in the rear electrode layer 20, and in detail, it may be 1 atomic % to 20 atomic %.

According to the present exemplary embodiment, the oxygen atoms may be easily included in the rear electrode layer 20 by providing break times during the process of depositing the molybdenum metal for forming the rear electrode layer 20 without adding a specific process. The alkali metal (e.g., sodium) inside the substrate 10 may be efficiently spread into the light absorbing layer 30 due to the oxygen atoms included in the rear electrode layer 20 during the heat treatment for manufacturing the solar cell 100. Therefore, the open voltage (Voc) is increased to improve efficiency of the solar cell 100.

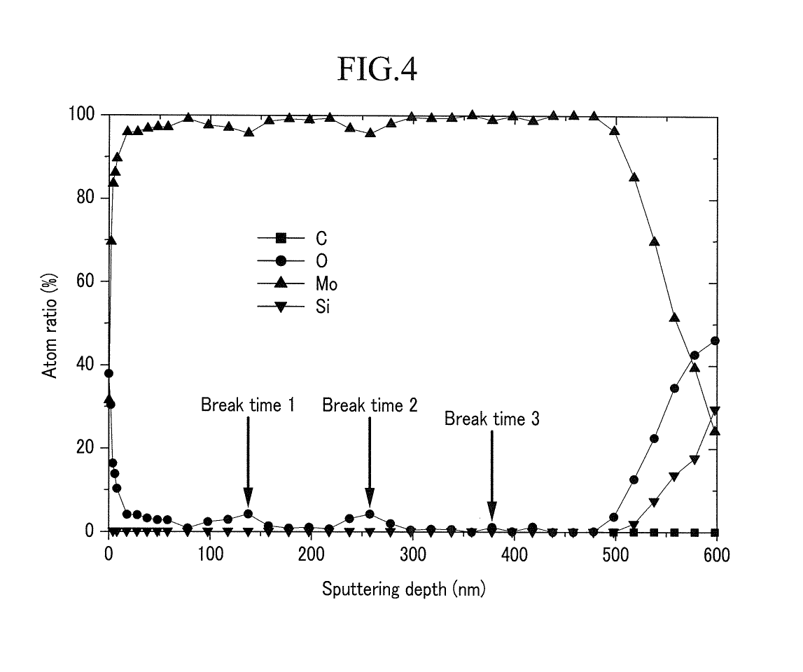

As shown in FIG. 4, the number of oxygen atoms is increased according to the break times in the process of depositing molybdenum. In the present exemplary embodiment, three break times are provided so that the oxygen atoms are provided at three time points.

Further, the molybdenum metal may be deposited at a relatively low pressure. In general, when the molybdenum is deposited through sputtering for forming the rear electrode layer 20, a great pressure promotes sufficient adherence of the rear electrode layer 20 with the substrate 10, and in this case, a residual stress characteristic of the rear electrode layer 20 is weakened or resistivity of the rear electrode is increased so that the thickness of the electrode must be increased. However, according to the present exemplary embodiment, when the molybdenum metal is deposited in the low pressure condition as described, a solar cell 100 with excellent adherence between the rear electrode layer 20 and the substrate 10 may be acquired.

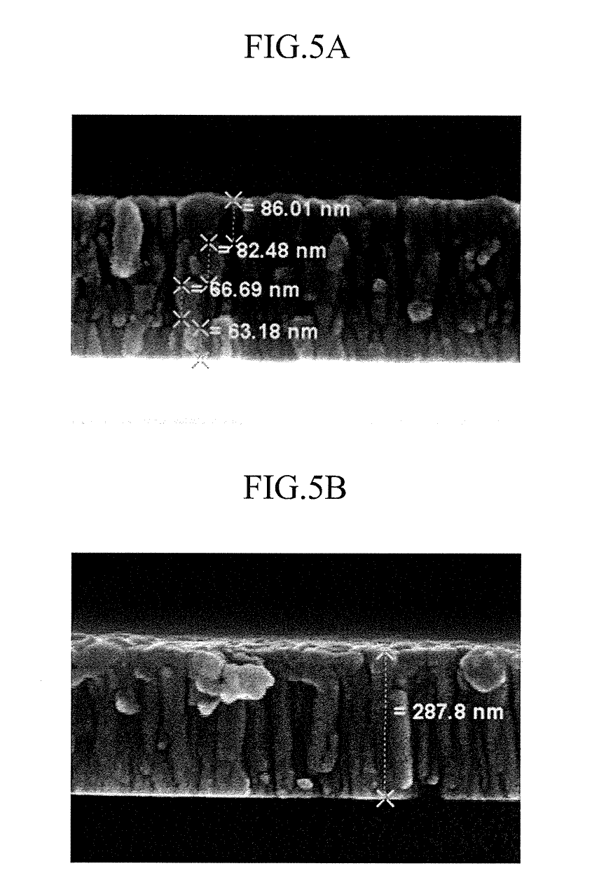

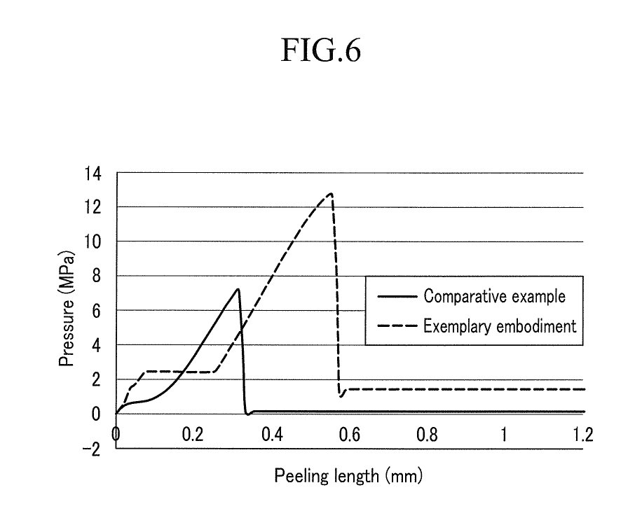

FIGS. 5A and 5B show photographs of a cross-section of a rear electrode layer captured by a scanning electron microscope (SEM) according to an exemplary embodiment and a comparative example, respectively, and FIG. 6 shows a graph of a result of a peel strength test according to an exemplary embodiment and a comparative example.

Exemplary Embodiment 1 (e.g., “Exemplary embodiment” of FIG. 6) represents a case in which three break times are provided when the rear electrode layer 20 is formed, and Comparative Example 1 (e.g., “Comparative example” of FIG. 6) represents a case in which molybdenum is continuously deposited, without a break time, to form the rear electrode layer. Regarding Exemplary Embodiment 1 and Comparative Example 1, molybdenum is deposited under the same conditions except for the break time. That is, the rear electrode layer 20 with the electrode thickness of about 300 nm is formed with a pressure of about 1.8 Pa and power of about 8 kW by using the sputtering method.

As shown in FIG. 5A, in the exemplary embodiment with three break times, four metal columnar grain layers (20₁-20₄) are formed on the rear electrode layer 20. In addition, in the case of continuous deposition without a break time, as shown in FIG. 5B, a single rear electrode layer 20 is formed without the separately identifiable columnar grain layers.

Regarding Exemplary Embodiment 1 and Comparative Example 1, peel strengths are estimated. FIG. 6 shows a graph of results of a peel strength test according to an exemplary embodiment and a comparative example. Regarding the rear electrode layer 20 of Exemplary Embodiment 1 and Comparative Example 1, pressure is applied in the thickness direction of the rear electrode layer 20 to estimate the peeling point. As shown in FIG. 6, the peeling point in Exemplary Embodiment 1 represents a point when the peeling pressure of about 13 MPa is applied, which shows excellent peel strength when compared to Comparative Example 1, which indicates peeling with a pressure of about 7 MPa.

Further, referring to Table 1 below, tape assessments were performed for Exemplary Embodiments 2, 3, 4, and 5 and Comparative Examples 2, 3, 4, and 5. Regarding Exemplary Embodiments 2, 3, 4, and 5, the deposition conditions are different, and the rear electrode layer 20 is formed under the condition of three break times. Regarding Comparative Examples 2, 3, 4, and 5, the rear electrode layer is formed with continuous deposition without a break time under the same deposition conditions as Exemplary Embodiments 2, 3, 4, and .5

The tape assessments are tested for Exemplary Embodiments 2, 3, 4, and 5 and Comparative Examples 2, 3, 4, and 5. That is, when a commercial 3M® tape (3M® is a registered trademark of 3M Company, St. Paul Minn.) is attached to and detached from the surface of the finished rear electrode layer 20, it is determined to fail (failures being indicated by an “X” in the “Tape test result” column) when a part of the rear electrode layer 20 is detached, and is conversely determined to pass (marked with an “O” in the “Tape test result” column) when no part of the rear electrode layer 20 is detached. Table 1 shows deposition conditions and tape test results of Exemplary Embodiments 2, 3, 4, and 5 and Comparative Examples 2, 3, 4, and 5.

TABLE 1

| | Sputtering | | Number | Total | Tape |
|---|---|---|---|---|---|
| | pressure | Sputtering | of break | thickness | test |
| | (Pa) | power (kW) | times | (nm) | result |
| Exemplary | 0.3 | 3 | 3 | 300 nm | ◯ |
| Embodiment 2 | | | | | |
| Comparative | | | 0 | | X |
| Example 2 | | | | | |
| Exemplary | 2 | 3 | 3 | | ◯ |
| Embodiment 3 | | | | | |
| Comparative | | | 0 | | X |
| Example 3 | | | | | |
| Exemplary | 0.3 | 8 | 3 | | ◯ |
| Embodiment 4 | | | | | |
| Comparative | | | 0 | | X |
| Example 4 | | | | | |
| Exemplary | 2 | 8 | 3 | | ◯ |
| Embodiment 5 | | | | | |
| Comparative | | | 0 | | X |
| Example 5 | | | | | |

As expressed in Table 1, Exemplary Embodiments 2 to 5 show excellent peel strengths irrespective of sputtering conditions. That is, according to Exemplary Embodiments 2 to 5, excellent adherence of the rear electrode layer 20 to the substrate 10 is acquired under the conditions of low sputtering pressure and high sputtering power

While multiple embodiments have been described, it is to be understood that the invention is not limited thereto, but is intended to cover various modifications and equivalent arrangements included within the spirit and scope of the appended claims, and their equivalents, as well as the description and drawings.

1. A solar cell comprising:
a substrate;
a rear electrode layer on the substrate, the rear electrode layer comprising a plurality of metal columnar grain layers;
a light absorbing layer on the rear electrode layer; and
a transparent electrode layer on the light absorbing layer.

2. The solar cell of claim 1, wherein each of the metal columnar grain layers comprises molybdenum.

3. The solar cell of claim 1, wherein a thickness of each of the metal columnar grain layers is between about 20 nm and about 500 nm.

4. The solar cell of claim 3, wherein the thickness of each of the metal columnar grain layers is between about 50 nm and about 100 nm.

5. The solar cell of claim 1, further comprising an interface between an adjacent pair of the metal columnar grain layers, the interface comprising oxygen atoms.

6. The solar cell of claim 5, wherein an amount of the oxygen atoms is between about 1 atomic % and about 70 atomic % of a total amount of atoms of the rear electrode layer.

7. The solar cell of claim 6, wherein the amount of the oxygen atoms is between about 1 atomic % and about 20 atomic % of the total amount of atoms of the rear electrode layer.

8. The solar cell of claim 1, wherein the rear electrode layer comprises no more than 9 metal columnar grain layers.

9. The solar cell of claim 1, wherein the light absorbing layer comprises at least one of Cu, In, Ga, or Se.

10. A method of forming a solar cell, the method comprising:
placing a substrate in a deposition chamber;
forming a rear electrode layer comprising a plurality of metal columnar grain layers;
forming a light absorbing layer on the rear electrode layer; and
forming a transparent electrode layer on the light absorbing layer.

11. The method of claim 10, wherein the forming the rear electrode layer comprises:
forming one of the metal columnar grain layers by depositing molybdenum on the substrate or on a previous one of the metal columnar grain layers; and
forming a next one of the metal columnar grain layers by depositing molybdenum on the one of the metal columnar grain layers following a break time after forming the one of the metal columnar grain layers.

12. The method of claim 11, wherein the break time is between about 1 second and about 1 hour.

13. The method of claim 11, wherein oxygen atoms are placed in the rear electrode layer during the break time.

14. The method of claim 13, wherein an amount of the oxygen atoms placed in the rear electrode layer corresponds to at least one of a length of the break time or a number of break times.

15. A method of forming a solar cell, the method comprising:
placing a substrate in a deposition chamber;
forming a rear electrode layer by:
depositing molybdenum on the substrate to form a first metal columnar grain layer; and
depositing molybdenum on the first metal columnar grain layer following a break time after forming the first metal columnar grain layer to form a second metal columnar grain layer on the first metal columnar grain layer.

16. The method of claim 15, wherein oxygen atoms are placed in the rear electrode layer during the break time.

17. The method of claim 16, wherein an amount of oxygen atoms corresponds to at least one of a length of the break time or a number of break times.

18. The method of claim 15, wherein the break time is between about 1 second and about 1 hour.

19. The method of claim 15, wherein the molybdenum is deposited under a pressure of about 0.05 Pa to about 5 Pa.

20. The method of claim 15, wherein the molybdenum is deposited by sputtering.
